(19) United States
(12) Patent Application Publication
(10) Pub. No.: US 2008/0161190 A1
(43) Pub. Date: Jul. 3, 2008

(54) Biomagnetic field measurement apparatus

(75) Inventors: In Seon Kim, Yuseong-gu (KR); Yong Ho Lee, Yuseong-gu (KR); Yong Ki Park, Yuseong-gu (KR)

Correspondence Address: THE WEBB LAW FIRM, P.C., 700 KOPPERS BUILDING, 436 SEVENTH AVENUE, PITTSBURGH, PA, 15219, US

(73) Assignee: Korea Research Institute of Standards and Science, Yuseong-gu (KR)

(21) Appl. No.: 11/821,939

(22) Filed: Jun. 26, 2007

(30) Foreign Application Priority Data
Nov. 14, 2006 (KR) 10-2006-0111926

(51) Int. Cl. G01R 33/035

(52) U.S. Cl. 505/162

(57) ABSTRACT

A biomagnetic field measurement apparatus according to the present invention comprises: a head part provided with SQUID sensors (Superconducting Quantum Interference Device) for measuring a magnetocardiogram, the sensors being arranged in a row in a right and left direction at a lower end portion of the head part and being spaced apart by a predetermined space, and a non-magnetic liquid coolant container for cooling the SQUID sensors; an electronic circuitry part for controlling the SQUID sensors and measuring a signal; a signal processing software part for acquiring and storing the signal detected by the electronic circuitry part to a PC, calculating the signal and thus transforming the signal to a magnetic signal or a current signal, then mapping and displaying the transformed signal; and a bed part made of a non-magnetic material, mounted at a lower side of the head part to be spaced apart therefrom and provided with a platy sliding bed for measuring a magnetocardiogram by using the SQUID sensors of the head part at a state that a man to be measured is laid thereon, a sliding rail for allowing the sliding bed to move thereon in a front and rear direction, an up and down moving device for moving the sliding bed, for adjusting a measuring position of the man to be measured, in an up and down direction for adjusting the position of the SQUID sensors of the head part, a right and left moving device for moving the sliding bed in a right and left direction, and a front and rear moving device for moving the sliding bed in a front and rear direction by a predetermined space.

The biomagnetic field measurement apparatus according to the present invention has advantages that since SQUID sensors are arranged in a row and a magnetocardiogram is measured by moving the bed in a predetermined space, it is not necessary for the high-priced SQUID sensors to be provided a lot in comparison with a conventional biomagnetic field measurement apparatus, and thus the apparatus is inexpensive, structurally simple and able to be downsized, a space taken up can be reduced and maintenance thereof is facilitated.

### TECHNICAL FIELD

The present invention relates to a biomagnetic field measurement apparatus, and more particularly, to a biomagnetic field measurement apparatus for measuring a magnetocardiogram using a Superconducting Quantum Interference Device (hereinafter briefly referred to as SQUID sensor).

### BACKGROUND ART

A biomagnetic field is a magnetic signal generated from the heart, brain, spinal cord, stomach, or the like of a human body, and it is possible to measure such biomagnetic field by using a SQUID sensor which is a high sensitivity magnetic sensor. A diagnosis using the biomagnetic field measurement is importantly used in a functional study and functional disease diagnosis of the heart or the like because it is contactless and non-destructive and capable of measuring precisely a minute change in an action current, which is occurred within the heart, on the basis of an excellent time and spatial resolution. Herein, a magnetocardiogram (MGC) measured from the heart represents a magnetic field signal or a magnetic field distribution generated from the heart.

A conventional biomagnetic field measurement apparatus for measuring a magnetocardiogram has a problem that the apparatus is expensive as many expensive SQUID sensors are required since the SQUID sensors are provided in a matrix of 36 (6×6), 42 (6×7), 48 (6×8), or the like. Further, there is a problem that it takes up much space as it has a great volume since the SQUID sensors are provided in a matrix and its maintenance according to a trouble is complicated as many SQUID sensors are provided.

### DISCLOSURE OF THE INVENTION

It is an object of the present invention to provide a biomagnetic field measurement apparatus, wherein it is inexpensive as high-priced SQUID sensors are not provided a lot and a space taken up can be reduced as the apparatus is downsized.

To achieve the above object, a biomagnetic field measurement apparatus according to the present invention comprises: a head part provided with SQUID sensors (Superconducting Quantum Interference Device) for measuring a magnetocardiogram, the sensors being arranged in a row in a right and left direction at a lower end portion of the head part and being spaced apart by a predetermined space, and a non-magnetic liquid coolant container for cooling the SQUID sensors; an electronic circuitry part for controlling the SQUID sensors and measuring a signal; a signal processing software part for acquiring and storing the signal detected by the electronic circuitry part to a PC, calculating the signal and thus transforming the signal to a magnetic signal or a current signal, then mapping and displaying the transformed signal; and a bed part made of a non-magnetic material, mounted at a lower side of the head part to be spaced apart therefrom and provided with a platy sliding bed for measuring a magnetocardiogram by using the SQUID sensors of the head part at a state that a man to be measured is laid thereon, a sliding rail for allowing the sliding bed to move thereon in a front and rear direction, an up and down moving device for moving the sliding bed, for adjusting a measuring position of the man to be measured, in an up and down direction for adjusting the position of the SQUID sensors of the head part, a right and left moving device for moving the sliding bed in a right and left direction, and a front and rear moving device for moving the sliding bed in a front and rear direction by a predetermined space.

Further, in the SQUID sensors of the present invention, four to nine SQUID sensors are arranged in a row.

Furthermore, a number of mapping point of the SQUID sensors by movement using the front and rear moving device is 36 to 54.

### BRIEF DESCRIPTION OF THE DRAWINGS

FIG. 1 is a perspective view illustrating a biomagnetic field measurement apparatus according to the present invention.

FIG. 2 is a perspective view illustrating a state that a sliding bed of the biomagnetic field measurement apparatus according to the present invention is moved at a state that a man to be measured is laid thereon.

FIG. 3 illustrates an example of a magnetocardiogram measurement for 6×6 point using the biomagnetic field measurement apparatus according to the present invention.

FIG. 4 illustrates an example in which a magnetocardiogram is measured for 6×8 point using the biomagnetic field measurement apparatus according to the present invention and a magnetic field distribution and a current source distribution are calculated and displayed by a signal processing software.

### DETAILED DESCRIPTION OF MAIN ELEMENTS

100: head part
110: SQUID sensor
120: non-magnetic liquid coolant container
130: electronic circuitry part
200: bed part
210: sliding bed
220: sliding rail
230: up and down moving device
240: right and left moving device
250: front and rear moving device

### BEST MODE FOR CARRYING OUT THE INVENTION

Practical and presently preferred embodiments of the present invention are illustrative as shown in the following Examples and Comparative Examples.

However, it will be appreciated that those skilled in the art, on consideration of this disclosure, may make modifications and improvements within the spirit and scope of the present invention.

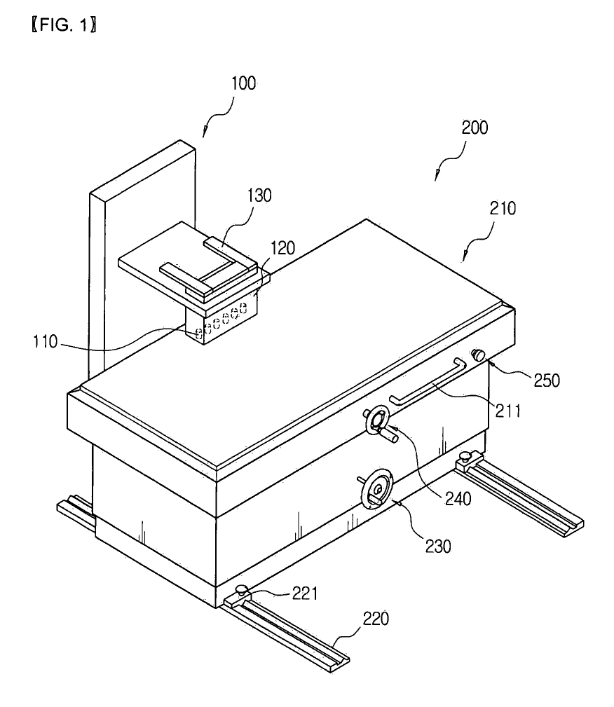

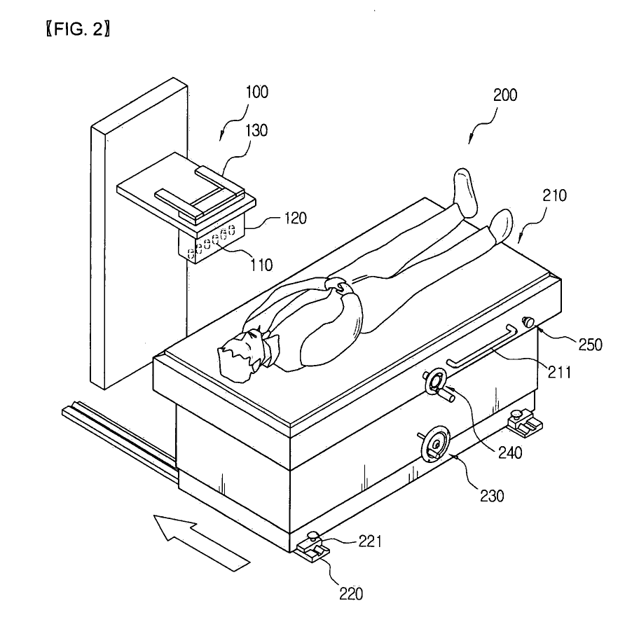

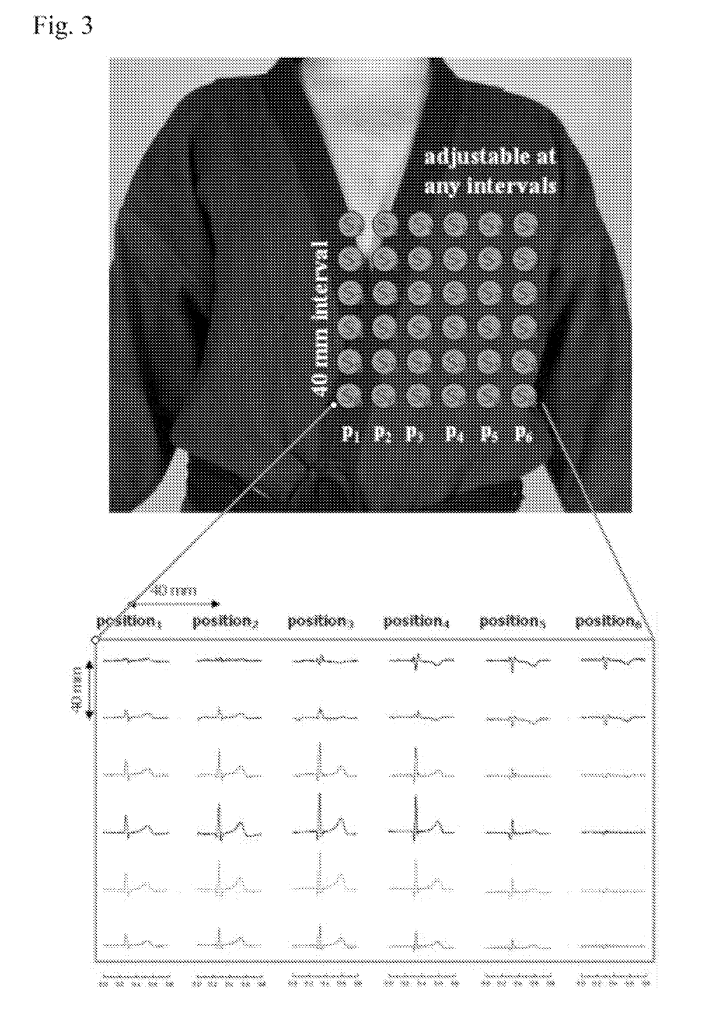

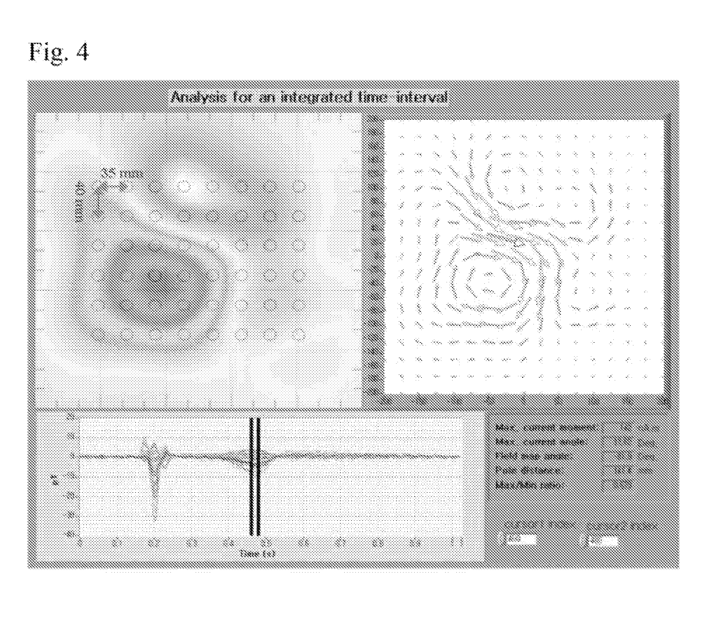

FIG. 1 is a perspective view illustrating a biomagnetic field measurement apparatus according to the present invention, FIG. 2 is a perspective view illustrating a state that a sliding bed of the biomagnetic field measurement apparatus according to the present invention is moved at a state that a man to be measured is laid thereon, FIG. 3 illustrates an example of a magnetocardiogram measurement for 6×6 point using the biomagnetic field measurement apparatus according to the present invention and FIG. 4 illustrates an example in which a magnetocardiogram is measured for 6×8 point using the biomagnetic field measurement apparatus according to the present invention and a magnetic field distribution and a current source distribution are calculated and displayed by a signal processing software.

As shown in the drawings, the biomagnetic field measurement apparatus according to the present invention includes a head part 100 provided with SQUID sensors 110 for measuring a magnetocardiogram, the sensors being arranged in a row in a right and left direction and being spaced apart by a predetermined space; an electronic circuitry part 130 for controlling the SQUID sensors 110 and measuring a signal; a signal processing software part for acquiring and storing the signal detected by the electronic circuitry part to a PC, calculating the signal and thus transforming the signal to a magnetic signal or a current signal, then mapping and displaying the transformed signal; and a bed part 200 provided with a platy sliding bed for measuring a magnetocardiogram by using the SQUID sensors of the head part at a state that a man to be measured is laid thereon, a sliding rail for allowing the sliding bed to move thereon in a front and rear direction, an up and down moving device for moving the sliding bed, for adjusting a measuring position of the man to be measured, in an up and down direction for adjusting the position of the SQUID sensors of the head part, a right and left moving device for moving the sliding bed in a right and left direction, and a front and rear moving device for moving the sliding bed in a front and rear direction by a predetermined space.

The head part 100 is provided with the SQUID sensors 110 at a lower end portion thereof and a non-magnetic liquid coolant container 120 is provided on an upper portion of the SQUID sensors 110. On an upper portion of the non-magnetic liquid coolant container 120 is provided the electronic circuitry part 130 for controlling the SQUID sensors 110 and measuring a signal.

The SQUID sensors 110 are provided at a lower end portion of the head part 100 and arranged in a row with a predetermined space in a longitudinal direction, along which the rectangular sliding bed 210 is mounted, i.e. in a right and left direction and measure a magnetocardiogram (MCG), i.e. a magnetic field signal or a magnetic field distribution generated from the heart. The SQUID sensor 110 is a device which transforms magnetic flux to voltage and has sensitivity which approaches a quantum mechanical measuring limit, in addition it is the measuring sensor with the most excellent sensitivity among electromagnetic sensors which have ever developed and is used importantly in a precise measurement for various kinds of electromagnetic quantity. This SQUID sensor 110 is used for measuring any physical quantity which is capable of being transformed to magnetic flux and is widely used in fields of precise measurement such as exploration of underground resources, detecting a submarine, non-destructive inspection of material, predicting earthquakes, low-noise amplifier, or the like as well as measurement for minute biomagnetic field generated from a human body, and a conventional SQUID sensor is used in the present invention.

In order to be used in signal measurement, the SQUID sensor 110 generally includes a cooling device.

The electronic circuitry part 130 controls the SQUID sensors 110 and measures the signal. The signal data detected by the electronic circuitry part 130 is acquired and stored to a PC by the software part (not shown), the signal data is calculated to transformed to a magnetic field signal data or a current signal data and then the transformed data is mapped and displayed.

The bed part 200 moves a man to be measured to a position, at which the SQUID sensor can measure; the bed part is made of non-magnetic material and installed at a lower portion of the head part 100 to be spaced apart from the lower portion of the head part 100, and is provided with the sliding bed 210, the sliding rail 220, the up and down moving device 230, the right and left moving device 240 and the front and rear moving device 250.

The sliding bed 210 is platy so as to measure a magnetocardiogram by using the SQUID sensors 110 of the head part 100 at a state that a man to be measured is laid thereon.

The sliding rail 220 allows the sliding bed 210, on which a man to be measured is laid, to move thereon in a front and rear direction so that the SQUID sensors 110 of the head part 100 can approach to a vicinity of the heart of the man to be measured. At a front side of the sliding bed 210 is provided a gripper 211 for moving the sliding bed so that a man who measures can easily move the sliding bed 210 in a front and rear direction.

As shown in FIG. 2, a magnetocardiogram is measured by using the front and rear moving device after moving the sliding bed 210 rearward to a position where the SQUID sensors 110 is located in the state that a man to be measured is laid on the sliding bed 210. The sliding rail 220 is provided with a locking device 221 which locks the sliding bed 210 so that the sliding bed 210 is not derailed after movement of the sliding bed 210 as shown in FIG. 2.

The up and down moving device 230 moves the sliding bed 210 in an up and down direction for adjusting a height of a measuring position of the man to be measured so that the position of the SQUID sensors 110 of the head 100 approaches to the vicinity of the heart of the man to be measured.

The right and left moving device 240 moves the sliding bed 210 in an right and left direction for adjusting a right and left position of the man to be measured so that the position of the SQUID sensors 110 of the head 100 approaches to the vicinity of the heart of the man to be measured.

The front and rear moving device 250 moves the sliding bed 210 by a predetermined space in front and rear direction, i.e. perpendicular to a direction in which the SQUID sensors 110 are arranged, so that a magnetocardiogram is measured by the SQUID sensors 110 and mapped. At this time, four to nine SQUID sensors are arranged in a row, and measure multi-position magnetocardiograms while the sliding bed 210 is moved in a front and rear direction by the front and rear moving device 250.

As such, four to nine SQUID sensors are arranged in a row and a magnetocardiogram is measured by moving the sliding bed 210 in a predetermined space, then there are advantages that it is not necessary for the high-priced SQUID sensors to be provided a lot in comparison with a conventional biomagnetic field measurement apparatus which is provided with the SQUID sensors by 36 (6×6), 42 (6×7), 48 (6×8), or the like, and thus the apparatus is structurally simple, inexpensive and can be downsized as volume thereof is reduced.

At this time, it is preferable that a number of mapping point of the SQUID sensors 110 by a movement of the front and rear moving device 250 is 36 (measurement by 6 times of the front and rear movement using 6 SQUID sensors) to 54 (measurement by 9 times of the front and rear movement using 6 SQUID sensors).

FIG. 3 illustrates that a number of mapping point of the SQUID sensors 110 is 36.

The above mentioned moving devices such as the up and down moving device 230, the right and left moving device 240 and the front and rear moving device 250 are well known devices in the art, conventional moving devices for moving up and down, right and left or front and rear may be used.

FIG. 4 illustrates an example in which a magnetocardiogram is measured for 6×8 point using the biomagnetic field measurement apparatus according to the present invention and a magnetic field distribution and a current source distribution are calculated and displayed by a signal processing software.

### INDUSTRIAL APPLICABILITY

As above described, the biomagnetic field measurement apparatus according to the present invention has advantages that since SQUID sensors are arranged in a row and a magnetocardiogram is measured by moving the bed in a predetermined space, it is not necessary for the high-priced SQUID sensors to be provided a lot in comparison with a conventional biomagnetic field measurement apparatus, and thus the apparatus is inexpensive, structurally simple and able to be downsized, a space taken up can be reduced and maintenance thereof is facilitated.

Those skilled in the art will appreciate that the conceptions and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

The invention claimed is:

1. A biomagnetic field measurement apparatus comprising:
a head part provided with SQUID sensors (Superconducting Quantum Interference Device) for measuring a magnetocardiogram, the sensors being arranged in a row in a right and left direction at a lower end portion of the head part and being spaced apart by a predetermined space, and a non-magnetic liquid coolant container for cooling the SQUID sensors;
an electronic circuitry part for controlling the SQUID sensors and measuring a signal;
a signal processing software part for acquiring and storing the signal detected by the electronic circuitry part to a PC, calculating the signal and thus transforming the signal to a magnetic signal or a current signal, then mapping and displaying the transformed signal; and
a bed part made of a non-magnetic material, mounted at a lower side of the head part to be spaced apart therefrom and provided with
a platy sliding bed for measuring a magnetocardiogram by using the SQUID sensors of the head part at a state that a man to be measured is laid thereon,
a sliding rail for allowing the sliding bed to move thereon in a front and rear direction,
an up and down moving device for moving the sliding bed, for adjusting a measuring position of the man to be measured, in an up and down direction for adjusting the position of the SQUID sensors of the head part,
a right and left moving device for moving the sliding bed in a right and left direction, and
a front and rear moving device for moving the sliding bed in a front and rear direction by a predetermined space.

2. The biomagnetic field measurement apparatus as set forth in claim 1, wherein four to nine SQUID sensors are arranged in a row.

3. The biomagnetic field measurement apparatus as set forth in claim 2, wherein a number of mapping point of the SQUID sensors by movement using the front and rear moving device is 36 to 54.
